(19) United States
(12) Patent Application Publication
(10) Pub. No.: US 2015/0028920 A1
(43) Pub. Date: Jan. 29, 2015

(54) MULTIPLEXER, LOOK-UP TABLE AND FPGA

(71) Applicant: SOITEC, Crolles Cedex (FR)

(72) Inventor: Richard Ferrant, Esquibien (FR)

(21) Appl. No.: 14/380,312

(22) PCT Filed: Feb. 11, 2013
(86) PCT No.: PCT/EP2013/052669

§ 371 Date: Aug. 21, 2014

(30) Foreign Application Priority Data
Mar. 6, 2012 (FR) 1252016

(51) Int. Cl. H03K 17/693; H03K 17/00; H03K 19/177

(52) U.S. Cl. CPC H03K 17/693; H03K 19/17728; H03K 17/005; H03K 2017/6878
USPC 326/38; 327/408

(57) ABSTRACT

The present invention relates to a multiplexer comprising at least a first input and a second input and one output connected to the first input via a first pass gate and to the second input via a second pass gate, wherein the first pass gate comprises at least a first double-gate transistor, and the second pass gate comprises at least a second double-gate transistor, and each of the first and second double-gate transistors has a first gate controlled based on a first control signal and a second gate controlled based on a second control signal. The invention further relates to a look-up table and a and an FPGA based on the multiplexer.

### CROSS-REFERENCE TO RELATED APPLICATIONS

This application is a national phase entry under 35 U.S.C. §371 of International Patent Application PCT/EP2013/052669, filed Feb. 11, 2013, designating the United States of America and published in English as International Patent Publication WO 2013/131717 A1 on Sep. 12, 2013, which claims the benefit under Article 8 of the Patent Cooperation Treaty and under 35 U.S.C. §119(e) to French Patent Application Serial No. 1252016, filed Mar. 6, 2012, the disclosure of each of which is hereby incorporated herein in its entirety by this reference.

### TECHNICAL FIELD

The present invention relates to a multiplexer, to a look-up table realized based on the multiplexer and to an FPGA based thereon. In particular, the invention relates to a multiplexer comprising at least a first input, and a second input; and one output, connected to the first input via a first pass gate and to the second input via a second pass gate. Additionally, the invention relates to a look-up table comprising at least a first storing means and a second storing means; and a first multiplexer; wherein, the first input of the first multiplexer is connected to the first storing means and the second input of the multiplexer is connected to the second storing means. Moreover, the invention relates to a FPGA comprising the look-up table, wherein the FPGA can be programmed by setting values in the first storing means and/or the second storing means.

### BACKGROUND

Look-up tables are generally used in order to retrieve stored data based on a plurality of inputs. In particular, the plurality of inputs can be considered as an address uniquely identifying each of the data stored in the look up table. Additionally, look-up tables can be used in order to implement FPGA logic. In particular, by appropriately setting the data stored in the registers of the look-up table, it is possible to program the table so as to obtain at the output of the look-up table any boolean combination of the inputs.

An exemplary look-up table 4000 is provided, for instance, in FIG. 4.

In particular, FIG. 4 illustrates a look up table 4000 having three control inputs A, B and C. Accordingly, the maximum number of registers 4020, which can be accessed by the three control inputs is eight. The output 4041 of the look up table 4000 is connected to each of the registers 4021-4028 via a plurality of pass gates 4071, 4072, 4091, 4092, etc. For instance, when the control inputs A, B and C are all at a high logic level, the pass gates 4071, 4081 and 4091 will be conducting, while all other pass gates of the look-up table 4000 will be open. This provides a connection between the output 4041 and the register 4021.

By appropriately setting the values of the registers 4020, it is possible to obtain on the output 4041 any Boolean combination of the control inputs A, B and C. This allows the implementation of a FPGA based on the look-up table 4000.

In the example of FIG. 4, for ease of illustration, the pass gates are represented as NMOS transistors only. In practice, the pass gates could be realized by using one NMOS transistor for each pass gate, one PMOS transistor for each pass gate, a complementary couple of NMOS and PMOS transistors for each pass gate, or any other structure that would allow the input of the pass gate to be connected to the output of the pass gate depending on the value of a control signal, such as bipolar transistors, etc.

As can be seen in FIG. 4, look-up table 4000 having three control inputs A, B and C requires the presence of fourteen transistors, in the case where each pass gate is realized by a single transistor. If the complementary CMOS approach is used, the number of transistors is doubled to twenty-eight.

More generally, the number of transistors increases with the number of control inputs “n”. In particular, the number of transistors, when realizing each pass gate with a single transistor, is given by formula (1) below

$$\# Transistors = {\sum }_{x = n \to 1} {2}^{x} \qquad ( 1 )$$

In the case where the pass gate is realized by a CMOS couple of NMOS and PMOS transistors, the number of transistors is doubled.

As can be seen, the number of transistors increases rapidly with the number of control inputs. As the silicon area and power consumption of the look-up table increase with the number of transistors, those values also increase rapidly with the number of control inputs. Conversely, the speed of the look-up table decreases with the number of transistors.

### BRIEF SUMMARY

It is therefore an object of the present invention to provide a multiplexer that can be realized with a reduced number of transistors. It is an additional object of the present invention to realize a look-up table based on such a multiplexer. It is a further object of the invention to realize an FPGA based thereon.

The present invention can relate to a multiplexer comprising at least a first input, and a second input; and one output, connected to the first input via a first pass gate and to the second input via a second pass gate, wherein the first pass gate comprises at least a first double-gate transistor, and the second pass gate comprises at least a second double-gate transistor, and each of the first and second double gate transistor has a first gate controlled based on a first control signal and a second gate controlled based on a second control signal.

Thanks to such approach, the multiplexer can multiplex the inputs with a reduced number of pass gates.

In some advantageous embodiments, the multiplexer can further comprise a first control input and a first negated control input; and a second control input and a second negated control input, wherein the first control signal is inputted to the first control input and the second control signal is inputted to the second control input, and a negated version of the first control signal is inputted to the first negated control input and a negated version of the second control signal is inputted to the second negated control input.

Thanks to such approach, the multiplexer can be driven in a simple and effective manner.

In some advantageous embodiments, the first gate of the first and second double gate transistor can be connected each to a different one among the first control input and the first negated control input, and the second gates of the first and second double gate transistor can be connected the same one among the second control input and the second negated control input, or the first gates of the first and second double gate transistor can be connected to the same one among the first control input or the first negated control input, and the second gates of the first and second double gate transistor can be connected each to a different one among the second control input and the second negated control input, or the first gates of the first and second double gate transistor can be connected each to a different one among the first control input and the first negated control input, and the second gates of the first and second double gate transistor can be connected each to a different one among the second control input and the second negated control input.

Thanks to such approach, the multiplexer can be realized in a flexible manner.

In some advantageous embodiments, the multiplexer can further comprise a third input, and/or a fourth input; wherein the output is further connected to the third input via a third pass gate and/or to the fourth input via a fourth pass gate, the third pass gate comprises at least a third double-gate transistor, and the fourth pass gate comprises at least a fourth double-gate transistor, and each of the third and fourth double gate transistor has a first gate controlled based on a first control signal and a second gate controlled based on a second control signal.

Thanks to such approach, the multiplexer can multiplex several inputs with a reduced number of pass gates.

In some advantageous embodiments, any of the double gate transistors can be any of a partially depleted SOI transistor, and/or a fully depleted SOI transistor, and/or a finfet.

Thanks to such approach, the multiplexer can be implemented in volume production.

In some advantageous embodiments, the threshold voltage of any of the double gate transistors can be driven by at least one among the first gate and/or second gate to a value which makes the transistor not conducting, independently on the voltage applied on the other gate.

Thanks to such approach, the multiplexer can be realized with a reduced number of double gate transistors.

Furthermore, the present invention can relate to a look-up table comprising at least a first storing means and a second storing means; and a first multiplexer according to any previous claim; wherein, the first input of the first multiplexer is connected to the first storing means and the second input of the multiplexer is connected to the second storing means.

Thanks to such approach, a look up table having a reduced number of transistors can be implemented. Accordingly, power consumption and silicon area can be reduced, while yeld and speed can be increased.

In some advantageous embodiments, the look-up table can further comprise a third storing means and a fourth storing means; a second multiplexer according to any of the previous embodiments; and a third multiplexer according to any of the previous embodiments; wherein, both the first and second multiplexer are controlled based on the first control signal and the second control signal, and the output of the first multiplexer is connected to the first input of the third multiplexer, and the output of the second multiplexer is connected to the second input of the third multiplexer.

Thanks to such approach, a modular construction of the look up table provides the flexibility to realize a look up table of any size.

Furthermore, the present invention can relate to a FPGA comprising a look-up table in accordance with the above embodiments, wherein the FPGA can be programmed by setting values in the first storing means and/or the second storing means.

Thanks to such approach, an FPGA having a reduced number of transistor can be implemented.

### BRIEF DESCRIPTION OF THE DRAWINGS

The invention will be described in more detail by way of example hereinafter using advantageous embodiments and with reference to the drawings. The described embodiments are only possible configurations in which the individual features may however, as described above, be implemented independently of each other or may be omitted. Equal elements illustrated in the drawings are provided with equal reference signs. Parts of the description relating to equal elements illustrated in the different drawings may be left out. In the drawings:

FIG. 1 schematically illustrates a multiplexer in accordance with an embodiment of the present invention;

FIG. 1B schematically illustrates a possible layout implementation of the multiplexer of FIG. 1;

FIG. 2 schematically illustrates the behaviour of the multiplexer of FIG. 1;

FIG. 3 schematically illustrates a look-up table in accordance with a further embodiment of the present invention;

FIG. 3B schematically illustrates a possible layout implementation of part of the look-up table of FIG. 3; and

FIG. 4 schematically illustrates a look-up table.

### DETAILED DESCRIPTION

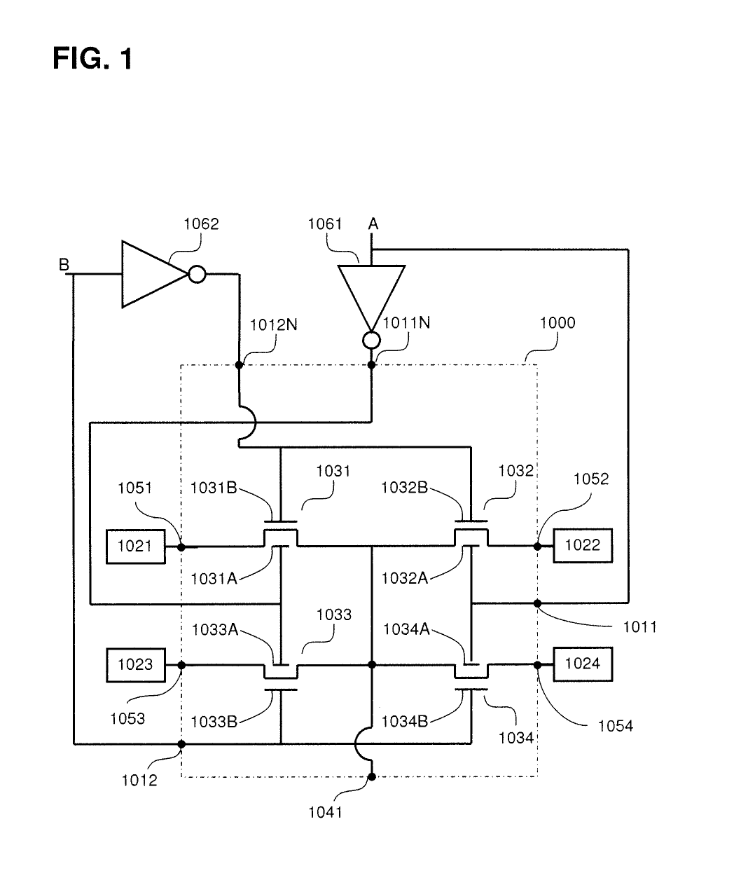

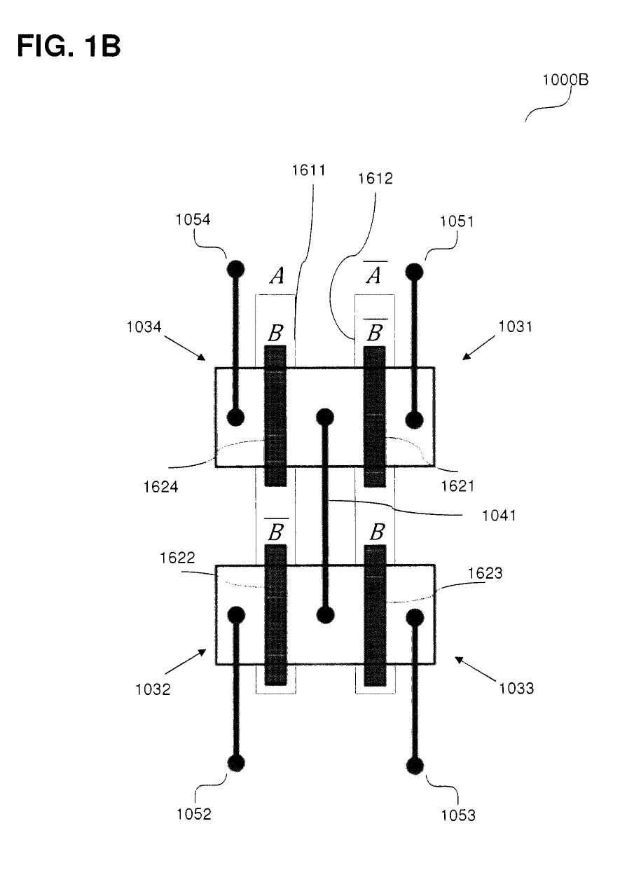

A multiplexer 1000 in accordance with the present invention is illustrated in FIG. 1. The multiplexer 1000 has four inputs 1051, 1052, 1053 and 1054 respectively connected to four registers 1021, 1022, 1023 and 1024. Additionally, the multiplexer 1000 has four control inputs 1011, 1011N, 1012 and 1012N for receiving control signals. Also, the multiplexer 1000 has an output port 1041, connected to the four inputs 1051-1054 via four pass gates 1031-1034. In particular, the open/close state of the pass gates is controlled via control signals inputted to the control inputs 1011, 1011N, 1012 and 1012N.

More specifically, the multiplexer 1000 is a 4-to-1 multiplexer, which allows the connection of one of the four registers 1021-1024 to the output port 1041, depending on the control signals inputted to control inputs 1011, 1011N, 1012 and 1012N. Even more specifically, the control signals inputted to control inputs 1011 and 1011N are derived from a single control signal A, which is inputted to the control input 1011 and, via a negation performed by inverter 1061, to the negated control input 1011N. Similarly, control signals inputted to control inputs 1012 and 1012N are derived from a single control signal B, which is inputted to the control input 1012 and, via a negation performed by inverter 1062, to the negated control input 1012N.

Accordingly, the multiplexer 1000 of FIG. 1 allows the selection of one of the four registers 1021-1024 to be connected to the output port 1041 via the pass gates 1031-1034, based on the values of control signals A and B. The working principle of the multiplexer will be described in details below.

Although the multiplexer 1000 has been described as comprising four pass gates 1031-1034, the present invention is not limited thereto. Alternatively, or in addition, the number of pass gates could be as low as two, thereby realizing a 2-to-1 multiplexer. For instance, this could be achieved by using any combination of two pass gates among pass gates 1031-1034. Still alternatively, or in addition, the number of pass gates could be higher.

Furthermore, although the multiplexer 1000 has been described as being connected to four registers 1021-1024, the present invention is not limited thereto. Alternatively, or in addition, instead of registers, any signal could be inputted to any of the inputs 1051-1054 of the multiplexer. For instance, any of the inputs 1051-1054 may be connected to signals generated by other circuits, as will be described below.

As can be seen in FIG. 1, in multiplexer 1000, the four pass gates 1031-1034 are realized by four double gate NMOS transistors. More specifically, each of the double gate transistors has a first gate and a second gate. In particular, double gate transistor realizing pass gate 1031 has a first gate 1031A and a second gate 1031B. Double gate transistor realizing pass gate 1032 has a first gate 1032A and a second gate 1032B. Double gate transistor realizing pass gate 1033 has a first gate 1033A and a second gate 1033B. Double gate transistor realizing pass gate 1034 has a first gate 1034A and a second gate 1034B.

FIG. 1B illustrates a possible layout implementation 1000B of the multiplexer 1000 of FIG. 1.

The layout 1000B comprises four double gate transistors, each one implementing one of pass gates 1031-1034.

The double gate transistors are organized on two rows, so that two vertically adjacent transistors can share a common back gate. In particular, the transistors realizing pass gates 1034 and 1032 share a common back gate 1611, connected to control signal A. Similarly the transistors realizing pass gates 1031 and 1033 share a common back gate 1611, connected to the negated version of control signal A. Accordingly, back gate 1611 implements first gate 1032A and first gate 1034A while back gate 1612 implements first gate 1031A and first gate 1033A.

This allows the layout to be compact and the number of contacts to the back gates 1611 and 1612 to be reduced.

Alternatively, or in addition, the vertically adjacent transistors could share a common top gate, so as to reduce the number of contacts to the top gates.

Additionally, the four transistors each have one source, drain and top gate. Top gate 1621 belongs to the transistor implementing pass gate 1031, and corresponds to second gate 1031 B. Similarly, top gates 1622, 1623, and 1624 each belong to the transistor implementing pass gate 1032, 1033, and 1034, and corresponds to second gate 1032B, 1033B, and 1034B, respectively.

Moreover, although the first gate 1031A-1034A of each transistor is realized, in the layout 1000B, as a back gate 1611-1612, while the second gate 1031B-1034B is realized as a top gate 1621-1624, the invention is not limited thereto and the gates could be switched, so as to realize the first gate 1031A-1034A as a top gate 1621-1624 and the second gate 1031B-1034B as a back gate 1611-1612.

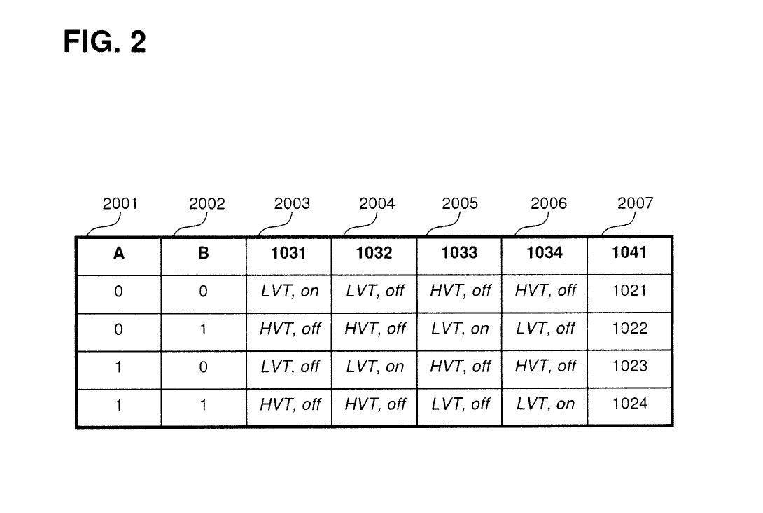

Although in the above embodiment, for ease of illustration, each pass gate is realized by a single, double-gate, NMOS transistor, the present invention is not limited thereto. Alternatively, or in addition, each pass gate could be realized by a double-gate PMOS transistor, and/or by a double-gate CMOS couple of NMOS and PMOS double-gate transistors. More generally, each pass gate 1031-1034 could be realized by a circuit having at least two control ports which behave as described with reference to FIG. 2.

The behaviour of the multiplexer 1000 will now be described with reference to FIGS. 1 and 2.

FIG. 2 represents a table schematically illustrating the operation of the multiplexer 1000 of FIG. 1. In particular, FIG. 2 has seven columns 2001-2007, each one of them having five rows. The top row of each column contains reference that correspond to the respective reference numerals in FIG. 1.

In particular, the first row of column 2001 contains reference sign A relating to control signal A of FIG. 1. The first row of column 2002 contains reference sign B relating to control signal B of FIG. 1. The first row of column 2003 contains reference sign 1031 relating to the status of pass gate 1031 of FIG. 1. The first row of column 2004 contains reference sign 1032 relating to the status of pass gate 1032 of FIG. 1. The first row of column 2005 contains reference sign 1033 relating to the status of pass gate 1033 of FIG. 1. The first row of column 2006 contains reference sign 1034 relating to the status of pass gate 1034 of FIG. 1. Finally, the first row of column 2007 contains reference sign 1041 relating to the value present on output port 1041 of FIG. 1, when the input signals A and B are given the values of the corresponding row in FIG. 2.

The second to fifth row of each of the columns 2001-2002 reports schematic logic values for the control signals A and B. For ease of illustration, only the values of control signals A and B are reported. It is to be understood that those signals are inputted to control inputs 1011 and 1012 respectively, while the negated version of control signals A and B inputted to negated control inputs 1011N and 1012N, respectively.

Following the example of FIG. 1, in which the pass gates 1031-1034 are realized with double gate NMOS transistors, the second to fifth rows of columns 2003-2006 report the status of each of the respective transistors, assuming they are of NMOS type. In particular, each of columns 2003-2006 reports two indications, separated by a comma: the term “LVT” indicates that the respective transistor has a low threshold voltage and the term “HVT” indicates that the respective transistor has a high threshold voltage. Moreover, the term “on” indicates that the respective transistor is conducting, i.e. closed, while the term “off” indicates that the respective transistor is not conducting, i.e. open.

When any one of the two gates of each of the double gate transistors is at a low logical level, the threshold voltage of the transistor is high, for instance above the power supply, and the transistor is open, that is, not conducting, independently of the signal inputted on the remaining gate. For instance, with reference to column 2005, a specific example will be described below.

In the second row of column 2005, both control signal A inputted to control input 1011 and control signal B inputted to control input 1012 have a low logic value. Accordingly, the double gate NMOS transistor realizing pass gate 1033 will be presented with a low logic value on its second gate 1033B. In turn, this will force its threshold voltage to a high value, as indicated by the term “HVT”. Even thought the first gate 1033A has a high logic value inputted thereon, due to the control signal A being inverted by inverter 1061 connected to negated control input 1011 N, this is not enough to close the transistor. Accordingly, the pass gate 1033 does not conduct, that is, remains open, as indicated by the term “off”.

In the fourth row of column 2005, control signal A has a high logic value while control signal B has a low logic value. Similarly as above, the low logic value on second gate 1033B forces a high threshold voltage “HVT” on the transistor. Additionally, the transistor is presented with a low logic value on the first gate 1033A. Therefore, the pass gate 1033 does not conduct, that is, remains open, as indicated by the term “off”.

In the fifth row of column 2005, both control signals A and B have a high logic value. In this case, the signal inputted to the second gate 1033B of the transistor via control input 1012 is at a high logic level, thereby forcing a low value of threshold voltage LVT on the transistor. In this situation, the behaviour of the transistor is then decided by the remaining logical value inputted on the remaining gate. Since the value inputted on the first gate 1033A via negated control input 1011 N is at a low logic value, the pass gate 1033 will be open, that is, not conducting, as indicated by the term “off”.

On the other hand, in the third row of column 2005, the pass gate 1033 is conducting, as indicated by the term “on”. In particular, the signal inputted on the second gate 1033B has a high value, thereby driving the threshold voltage of the transistor to a low level

“LVT”. At the same time, the value inputted on the first gate 1033A has a high logical value. Accordingly, the transistor is closed and the pass gate is conducting.

More generally, due to the effect of one of the two gates of each of the double gate transistor, the threshold voltage can be set at a high value HVT or at a low value LVT. When set at a high value HVT, the effect of the remaining gate is not enough for closing the transistor. When set at LVT, the transistor is closed or open, depending on the value on the remaining gate. This can be achieved, for instance, by using SOI fully depleted (FD) transistors, SOI partially depleted (PD) transistors, and/or Finfets.

Although in the example above, the effect on the threshold voltage has been exemplified as being driven by one of the two gates 1033A or 1033B, the present invention is not limited thereto. In particular, the two gates may have a symmetrical effect on the threshold voltage of the transistors. Accordingly, for any of the transistor, the connections to the two gates could be inverted.

Alternatively, or in addition, one of the two gates may have a larger impact than the other gate on the threshold voltage. For instance, in the case of FDSOI transistors, a higher and appropriate voltage may have to be applied on back gate, compared to the case of a symmetric transistor, in order to achieve the same effect.

The usage of double gate transistors can be advantageous for implementations with a power supply (VDD) below 1V, with a nominal threshold voltage in the range of 0.3-0.4V or more. By nominal threshold voltage, it is intended the threshold voltage of the transistor when the second gate is at 0V.

For instance, an advantageous implementation could use a VDD around 0.5V with a nominal VT at 0.6V. In the case of an NMOS, if only one gate is high the transistor would then be off, as the single transistor would not be capable of overcoming the high threshold voltage, while, if both gates are high, the threshold voltage is lowered and the transistor would be on.

The remaining cases, corresponding to column 2003, 2004 and 2006 can be derived from the described behaviour of column 2005.

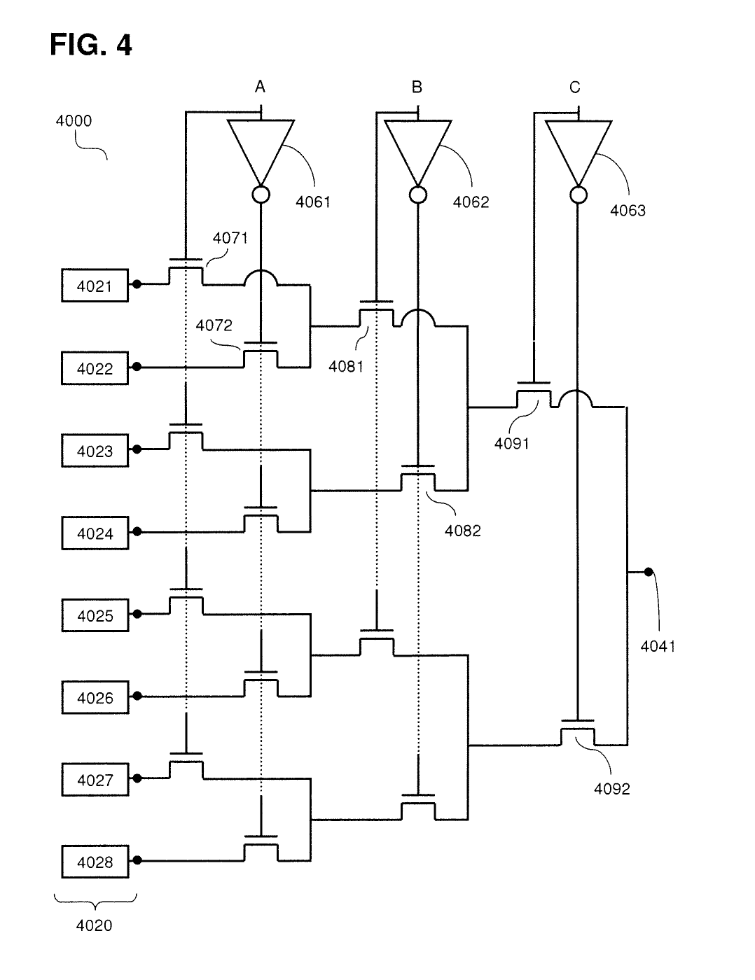

Accordingly, as can be seen in FIG. 1, when compared to FIG. 4, the present invention allows the realization of a 4-to-1 multiplexer by using only four transistors for pass gates 1031-1034 instead of six transistors, as is in the case of FIG. 4. Therefore, the multiplexer of FIG. 1 achieves the same functionality with a reduced number of transistors. In turn, this corresponds to providing the same functionality with less silicon area, less power and faster speed.

Although the multiplexer of FIG. 1 has been described as being a 4-to-1 multiplexer, the present invention is not limited thereto. Alternatively, or in addition, the invention could be implemented as a 2-to-1 multiplexer for instance, by using any combination of two pass gates among pass gates 1031-1034. Still alternatively, or in addition, the invention could be implemented as a 3-to-1 multiplexer for instance, by using any combination of three pass gates among pass gates 1031-1034. More generally, any multiplexing ratio can be implemented.

In Multiplexer 1000, the pass gates 1031-1034 have been described as being realized with a single double gate NMOS transistor. However, the present invention is not limited thereto. Alternatively, or in addition, any of the pass gates could be realized with a double gate PMOS transistor, or with a CMOS complementary couple of a double gate NMOS and a double gate PMOS transistors. Still alternatively, or in addition, any structure which allows a behaviour such as the one illustrated in FIG. 2 could be implemented.

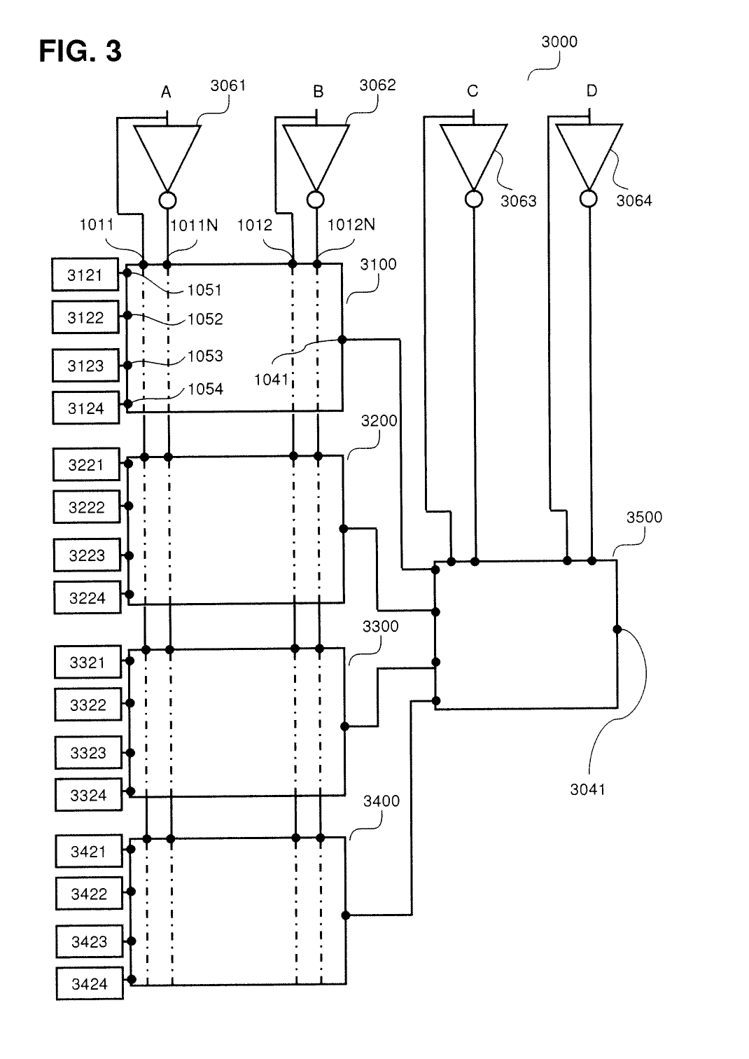

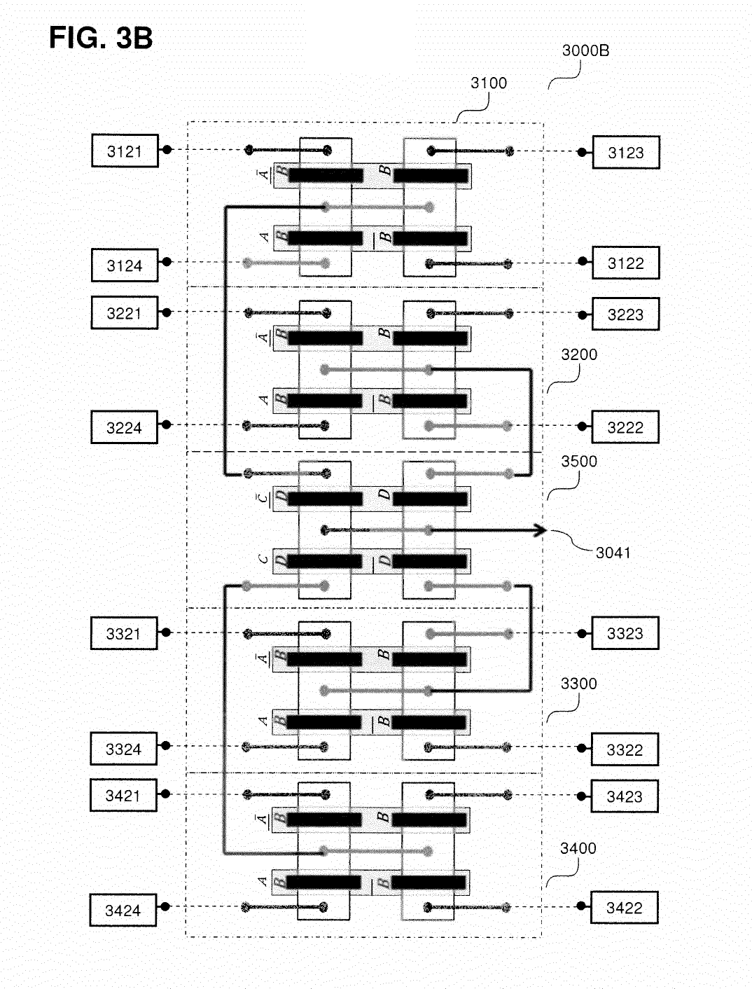

FIG. 3 illustrates a further embodiment, in accordance with the present invention.

In particular, FIG. 3 illustrates a look-up table 3000, which is realized by using five multiplexers 1000 as defined in the above-described embodiment. More specifically, each of the multiplexers 3100-3500 correspond to the multiplexer 1000 of FIG. 1. For ease of illustration, only the inputs of multiplexer 3100 have been explicitly assigned reference numerals corresponding to the ones used in FIG. 1. It is nevertheless intended that the illustrated inputs of multiplexers 3200-3500 correspond to those of multiplexer 3100.

Each of multiplexers 3100-3400 has inputs 1051-1054 connected to four registers. For instance, input 1051-1054 of multiplexer 3100 are connected to registers 3121-3124. On the other hand, inputs 1051-1054 of multiplexer 3500 are connected to output 1041 of multiplexers 3100-3400. In other words, the five multiplexers 3100-3500 are five 4-to-1 multiplexers, wherein the multiplexers 3100-3400 are connected to registers while multiplexer 3500 is connected in cascade to the four outputs of the multiplexers 3100-3400.

The control signals of the multiplexers 3100-3400 are shared. In particular, the control inputs 1011, 1011N, 1012, and 1012N are all connected to control signal A, the negated version of control signal A, control signal B, and the negated version of control signal B, respectively. Accordingly, for instance, when control signals A and B are set at 0 and 0, the output 1041 of multiplexer 3100 will be connected to register 3121. Similarly, the output 1041 of multiplexer 3200 will be connected to register 3221, the output 1041 of multiplexer 3300 will be connected to register 3321 and the output 1041 of multiplexer 3400 will be connected to register 3421.

On the other hand, the control signals C and D, as well as their respective negated versions are connected to the control inputs of multiplexer 3500. In particular, control signal C, its negated version, control signal D and its negated version are connected to control inputs 1011, 1011N, 1012 and 1012N.

Therefore, multiplexer 3500 allows a further level of selection between the outputs of multiplexers 3100-3500. With reference to the example above in which control signals A and B are set at 0 and 0, by setting control signals C and D as 0 and 0, the register 3121 will be connected to the output 3041 of the look up table 3000, corresponding to the output 1041 of multiplexer 3500.

Accordingly, the structure realized in FIG. 3 allows the connection of sixteen registers to one output port 3041 by means of five multiplexers 3100-3500. In turn, this means that the look up table 3000 can operate with twenty double gate transistors, in case each of the multiplexers 3100-3500 is realized as illustrated in the embodiment of FIG. 1. This provides an advantage over the corresponding realization following the technique illustrated in FIG. 4. In fact, such an architecture, when addressing 16 registers, requires the presence of thirty transistors.

Therefore, the number of transistors is reduced, which implies a smaller use of silicon area. This, in turn, means that costs are reduced and yeld is increased. Additionally, the signal going from register 3121 to output 3041 goes through only two transistors. In the architecture of FIG. 4, the same signal would go through four transistors. In turns, this implies that the signal would be slower in getting to the output. Moreover, since the signal has to go through less transistors, there is a reduced need for repeaters. This further improves the speed, while reducing the area, power consumption, and costs.

FIG. 3B illustrate a possible layout implementation 3000B of the look-up table 3000.

As can be seen, although the present invention is not limited to this and the multiplexers 3100-3500 can be placed in any order, the layout can advantageously be realized on a single row, by aligning the plurality of multiplexers 3100-3500. Each of the plurality of multiplexers 3100-3500 can be realized in a manner similar to the one illustrated in layout 1000B.

Thanks to such arrangement, the registers 3121-3424 can be placed on the two sides of the layout 3000B, which facilitates connection to the registers, such as connections for selecting and setting the registers, as well as power connections.

The connections of the registers 3121-3424 to the multiplexers 3100-3400 are illustrated by dotted lines, so as to indicate that those are logical connections and not necessarily physical connections shaped as such. For instance, the registers may be placed in a staggered manner, on one or more sides of the layout 3000B. Alternatively, or in addition, the registers may be placed in a single row but the pitch of the registers may be larger than the pitch of the corresponding connections in multiplexers 3100-3400, since multiplexer 3500, placed between multiplexers 3200 and 3300 does not require a connection to the registers.

Additionally, the placement of multiplexer 3500 in between multiplexers 3100, 3200 and 3300, 3400, allows the connections from the output 1041 of each of multiplexers 3100-3400, to be routed to the inputs of multiplexer 3500 on a single level of metal, with no overlapping.

1. A multiplexer comprising:
a first input;
a second input; and
an output connected to the first input via a first pass gate and to the second input via a second pass gate, wherein the first pass gate comprises at least a first double-gate transistor, and the second pass gate comprises at least a second double-gate transistor, and each of the first double-gate transistor and the second double-gate transistor has a first gate controlled based on a first control signal (A) and a second gate controlled based on a second control signal (B).

2. The multiplexer of claim 1, further comprising:
a first control input and a first negated control input; and
a second control input and a second negated control input, wherein the first control signal (A) is inputted to the first control input and the second control signal (B) is inputted to the second control input, and a negated version of the first control signal is inputted to the first negated control input and a negated version of the second control signal is inputted to the second negated control input.

3. The multiplexer of claim 2, wherein the first gates of the first and second double gate transistors are each connected to a different one among the first control input and the first negated control input, and the second gates of the first and second double gate transistors are connected to the same one among the second control input and the second negated control input.

4. The multiplexer according to claim 1, further comprising:
a third input, and a fourth input;
wherein the output is further connected to the third input via a third pass gate and to the fourth input via a fourth pass gate,
wherein the third pass gate comprises at least a third double-gate transistor, and the fourth pass gate comprises at least a fourth double-gate transistor, and
wherein each of the third and fourth double gate transistor has a first gate controlled based on the first control signal (A) and a second gate controlled based on the second control signal (B).

5. The multiplexer of claim 1, wherein any of the first and second double gate transistors comprises at least one of a partially depleted SOI transistor, a fully depleted SOI transistor, and a finfet.

6. The multiplexer of claim 1 wherein a threshold voltage of any of the first and second double gate transistors is driven by one of the first gate and the second gate to a value which makes the transistor not conducting, independent of a voltage applied to the other of the first gate and the second gate.

7. A look-up table comprising:
a first storing means and a second storing means; and
at least a first multiplexer comprising:
a first input;
a second input; and
an output connected to the first input via a first pass gate and to the second input via a second pass gate, wherein the first pass gate comprises at least a first double-gate transistor, and the second pass gate comprises at least a second double-gate transistor, and each of the first double-gate transistor and the second double-gate transistor has a first gate controlled based on a first control signal (A) and a second gate controlled based on a second control signal;
wherein the first input of the first multiplexer is connected to the first storing means and the second input of the multiplexer is connected to the second storing means.

8. The look-up table of claim 7, further comprising:
a third storing mean and a fourth storing means;
wherein the at least a first multiplexer comprises a second multiplexer and a third multiplexer;
wherein both the first multiplexer and the second multiplexer are controlled based on the first control signal (A) and the second control signal (B); and
wherein the output of the first multiplexer is connected to the first input of the third multiplexer, and the output of the second multiplexer is connected to the second input of the third multiplexer.

9. An FPGA comprising a look-up table as recited in claim 7, wherein the FPGA is programmable by setting values in the first storing means and the second storing means.

10. The multiplexer of claim 2, wherein the first gates of the first and second double gate transistors are each connected to the same one among the first control input and the first negated control input, and the second gates of the first and second double gate transistors are each connected to a different one among the second control input and the second negated control input.

11. The multiplexer of claim 2, wherein the first gates of the first and second double gate transistors are each connected to a different one among the first control input and the first negated control input, and the second gates of the first and second double gate transistors are each connected to a different one among the second control input and the second negated control input.

12. The multiplexer according to claim 1, further comprising:
a third input;
wherein the output is further connected to the third input via a third pass gate,
wherein the third pass gate comprises at least a third double-gate transistor, and
wherein the third double gate transistor has a first gate controlled based on the first control signal (A) and a second gate controlled based on the second control signal (B).
